(19) United States
(12) Patent Application Publication
(10) Pub. No.: US 2002/0057523 A1
(43) Pub. Date: May 16, 2002

(54) Encoder device

(76) Inventor: Takahiro Sakaguchi, Tokyo (JP)

Correspondence Address: Anderson, Kill & Olick, P.C., 1251 Avenue of the Americas, New York, NY, 10020-1182, US

(21) Appl. No.: 09/841,085

(22) Filed: Apr. 24, 2001

(30) Foreign Application Priority Data
Apr. 27, 2000 (JP) 2000-128050

(51) Int. Cl. H03M 11/00

(52) U.S. Cl. 360/110

(57) ABSTRACT

An encoder device has a main scale with a plurality of slit-like openings at regular intervals, a light-emitting element for emitting and directing substantially parallel rays of light toward the main scale, a light-receiving element including four light-receiving members for receiving light emitted from the light-emitting means via the slit-like openings in the main scale, and a detection unit for detecting a displacement of the main scale by using output signals output from the light-receiving element. The first light-receiving member and the second light-receiving member are positioned a distance apart such that a signal having a phase difference of approximately 270 degrees is obtained therefrom, the first light-receiving member and the third light-receiving member are positioned a distance apart such that a signal having a phase difference of approximately 180 degrees is obtained therefrom, the second light-receiving member and the fourth light-receiving member positioned a distance apart such that a signal having a phase difference of approximately 180 degrees is obtained therefrom, the four light-receiving members are positioned so as to be in an order of the third light-receiving member, first light-receiving member, the second light-receiving member and the fourth light-receiving member in the direction of displacement of the main scale. Accordingly, it is possible to bring the light-emitting member and the light-receiving members closer together and thus make the encoder device slimmer.

### BACKGROUND OF THE INVENTION

1. Field of the Invention

The present invention relates generally to an encoder device, and more particularly, to an improved optical encoder device that is slimmer while still providing highly accurate encoder output.

2. Description of the Related Art

In a magnetic disk drive, for example, a head carriage having a magnetic head is moved in a radial direction of a disk and the magnetic head is made to trace a selected track as the position of the head carriage is detected by the encoder device. Efforts are underway to make encoder devices of this type slimmer and more compact while still providing highly accurate encoder output.

The conventional encoder device has two light-receiving elements such as photodiodes placed 90 degrees apart, with two signals phase A and phase B having the same periods being output from light-receiving elements that receive the light from the light-emitting elements. From the two signals phase A and phase B the direction and distance that the head carriage has traveled is obtained.

More recently, in an effort to obtain more accurate encoder device output, four light-receiving elements have come to be used and four signals phase A, phase B, inverted phase A and inverted phase B extracted and the phase A and inverted phase A, as well as the phase B and the inverted phase B, are differentially amplified.

FIG. 1 is a schematic structural diagram of a conventional encoder device. As indicated in the diagram, in the conventional encoder device 1 the light-receiving element 2A and the light-receiving element 2B are disposed so as to have phases 90 degrees different from each other, the light-receiving element 2a of the inverted phase A and the light-receiving element 2A are disposed so as to have phases 180 degrees different from each other and the light-receiving element 2b of the inverted phase B and the light-receiving element 2B are disposed so as to have phases 180 degrees different from each other.

Additionally, in the conventional encoder device 1 a light-emitting element 3 is disposed at a location opposite the light-receiving elements 2A, 2B, 2a and 2b, with the light-receiving elements 2A, 2B, 2a and 2b symmetrically disposed with respect to a centerline of the light-emitting element 3. A main scale 5 made of a single piece of plastic is provided between a lens 3a of the light-emitting element 3 and the light-receiving elements 2A, 2B, 2a and 2b. The main scale 5 has slits 4 spaced at regular intervals, the slits 4 being shown in FIG. 1 as blank openings in the main scale 5.

Light emitted from the light-emitting element 3 is diffused at predetermined angles by the lens 3a so as to reach the light-receiving elements 2A, 2B, 2a and 2b. When the main scale 5, which is movable, moves in a direction of displacement D with respect to the light-emitting element 3, the light emitted from the light-emitting element 3 passes through the slits 4 in the main scale 5 and strikes the light-receiving elements 2A, 2B, 2a and 2b. The intensity of the light received at each of the light-receiving elements 2A, 2B, 2a and 2b varies as the main scale 5 moves and its position changes with respect to the light-receiving elements 2A, 2B, 2a and 2b.

As a result, a waveform signal is obtained from each of the light-receiving elements 2A, 2B, 2a and 2b which corresponds to variations in the level of light received at the light-receiving elements 2A, 2B, 2a and 2b as the main scale 5 changes position with respect to the light-receiving elements 2A, 2B, 2a and 2b. Signals from the light-receiving elements 2A, 2B, 2a and 2b are input into a circuit not shown in the diagram, so that a phase A signal output from the light-receiving element 2A and a phase a signal output from the light-receiving element 2a are differentially amplified to obtain an A′ phase signal (=A−a) and, similarly, a phase B signal output from the light-receiving element 2B and a phase b signal output from the light-receiving element 2b are differentially amplified to obtain a B′ phase signal (=B−b). The A′ phase signal and the B′ phase signal have phases 90 degrees different from each other.

The arrangement of the light-receiving elements 2A, 2B, 2a and 2b is not important so long as two signals —phase A signals and phase B signals—having phases 90 degrees different from each other and having the same period are output from the encoder device.

FIG. 2 is a diagram showing the conventional arrangement of the light-receiving elements 2A, 2B, 2a and 2b.

As shown in the diagram, light-receiving element 2B is positioned to one side of light-receiving element 2A so as to have a phase 90 degrees different from that of light-receiving element 2A, and light-receiving element 2a is positioned to one side of light-receiving element 2b so as to have a phase 90 degrees different from that of light-receiving element 2b.

By positioning light-receiving elements 2A, 2B, 2a and 2b as described above, the light-receiving elements 2A, 2B, 2a and 2b are spaced an equal distance apart, that is, are spaced so as have a phase difference of 90 degrees. With such an arrangement of the light-receiving elements 2A, 2B, 2a and 2b, interference between the light-receiving elements 2A, 2B, 2a and 2b can be reduced and the sensitivity of the light-receiving elements 2A, 2B, 2a and 2b can be improved.

However, the conventional encoder device 1 having the structure described above employs a light-emitting diode having a large-radius lens 3a, secures a region of parallel rays of light, and positions the light-receiving elements 2A, 2B, 2a and 2b in range of that region so as to secure a reliable gap between the main scale 5 and the light-receiving elements 2A, 2B, 2a and 2b. Yet the conventional encoder device uses a light-emitting element 3 with a small-diameter lens 3b in order to allow the encoder device as a whole to be made relatively thin, so light-receiving elements 2B and 2a are positioned also within a region in which rays of light from the light-emitting element 3a disperse.

As a result, it is necessary to heighten the degree of precision with which the encoder device is assembled, in particular the precision with which the light-receiving elements 2A, 2B, 2a and 2b, the light-emitting member 3 and the main scale 5 are assembled, in order to reliably obtain the correct gap. Such precision assembly of components is time-consuming, with the necessary post-assembly inspections revealing an inevitable and increasing percentage of defectively assembled devices.

For example, the range obtained from the region of substantially parallel rays of light of the light-emitting diode amounts to a region enclosed by a radial arc approximately ⅓ of the lens radius. If the main scale 5 pitch is 0.375 mm, then the outer edge of the row of light-receiving elements 2A, 2B, 2a and 2b is app. 0.66 mm, requiring a lens radius at least three times as large or approximately 1.98 mm.

At the same time, however, the radius of the lenses of the light-emitting diodes used in thin encoders is on the order of 0.5 mm. If as a result the light-receiving elements 2A, 2B, 2a and 2b are positioned too closely together, then there is the danger that they will become electrically conductive, making the conventional design for acquiring substantially parallel rays of light unsuitable. In addition, the size of the chip of the light-emitting element is a cube approximately 0.3 mm in length on each side, which is too small with respect to the lens 3b radius to be ignored. In other words, although such a light-emitting element can function as a light source and generate a region of substantially parallel rays of light, the edges of such a region fray rapidly and produce diffuse light rays.

### SUMMARY OF THE INVENTION

Accordingly, it is an object of the present invention to provide an improved and useful encoder device in which the above-mentioned disadvantage is eliminated.

The above-described object of the present invention is achieved by an encoder device comprising:

a main scale with a plurality of slit-like openings at regular intervals;

a light-emitting element for emitting and directing substantially parallel rays of light toward the main scale;

a light-receiving element including four light-receiving members for receiving light emitted from the light-emitting means via the slit-like openings in the main scale; and

a detection unit for detecting a displacement of the main scale by using output signals output from the light-receiving element,

the first light-receiving member and the second light-receiving member positioned a distance apart such that a signal having a phase difference of approximately 270 degrees is obtained therefrom,

the first light-receiving member and the third light-receiving member positioned a distance apart such that a signal having a phase difference of approximately 180 degrees is obtained therefrom,

the second light-receiving member and the fourth light-receiving member positioned a distance apart such that a signal having a phase difference of approximately 180 degrees is obtained therefrom,

the four light-receiving members being positioned so as to be in an order of the third light-receiving member, the first light-receiving member, the second light-receiving member and the fourth light-receiving member in a direction of displacement of the main scale.

According to the invention described above, the distance between each of the light-receiving elements can be reduced while accurate, interference-free output signals can still be reliably obtained from each of the light-receiving elements, allowing the encoder device to be made slimmer and more compact than the conventional encoder device.

### BRIEF DESCRIPTION OF THE DRAWINGS

These and other objects, features, aspects and advantages of the present invention will become better understood and more apparent from the following description, appended claims and accompanying drawings, wherein:

FIG. 1 is a schematic structural diagram of a conventional encoder device;

FIG. 2 is a diagram showing the conventional arrangement of the light-receiving elements 2A, 2B, 2a and 2b;

FIG. 3 is a structural diagram of a magnetic disk drive employing an embodiment of an encoder device according to the present invention;

FIG. 4 is a front view of an installed state of an encoder device for detecting the position of a head carriage;

FIGS. 5A, 5B, 5C and 5D are front, plan, side and partial expanded views, respectively, of the encoder device according to the present invention;

FIG. 6 is a plan view of the relative positions of the main scale, light source and light-receiving elements in a first detection operation state;

FIG. 7 is a block diagram showing a connection between each of the light-receiving elements and the differential amplifier;

FIG. 8 is a schematized view of the relative positions between the light source, light-receiving elements and main scale openings;

FIG. 9 is a graph (graph I) showing an output voltage waveform output from the light-receiving elements in response to the position of the main scale;

FIG. 10 is a graph (graph II) showing an output voltage waveform output from the light-receiving elements when the main scale has been displaced in the direction of displacement from the position shown in FIG. 9 by an amount equal to the width L1 of one of the openings in the main scale;

FIG. 11 is a plan view of a second detection operation state in which the main scale has moved in the direction of displacement D by an amount equivalent to ¼ L1 with respect to the state shown in FIG. 6;

FIG. 12 is a plan view of a state of a third detection operation state in which the main scale has moved in the direction of displacement D by an amount equivalent to ½ L1 with respect to the state shown in FIG. 11;

FIG. 13 is a plan view of a fourth detection operation state in which the main scale has moved in the direction of displacement D by an amount equivalent to ¼ L1 with respect to the state shown in FIG. 12; and

FIG. 14 is a plan view of a fifth detection operation state in which the main scale has moved in the direction of displacement D by an amount equivalent to ¼ L1 with respect to the state shown in FIG. 13.

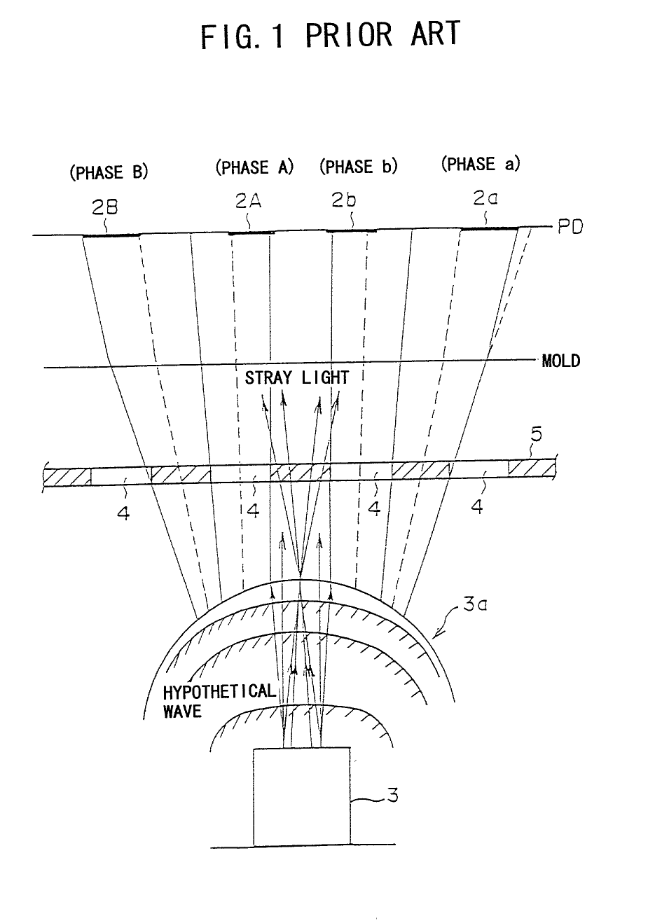

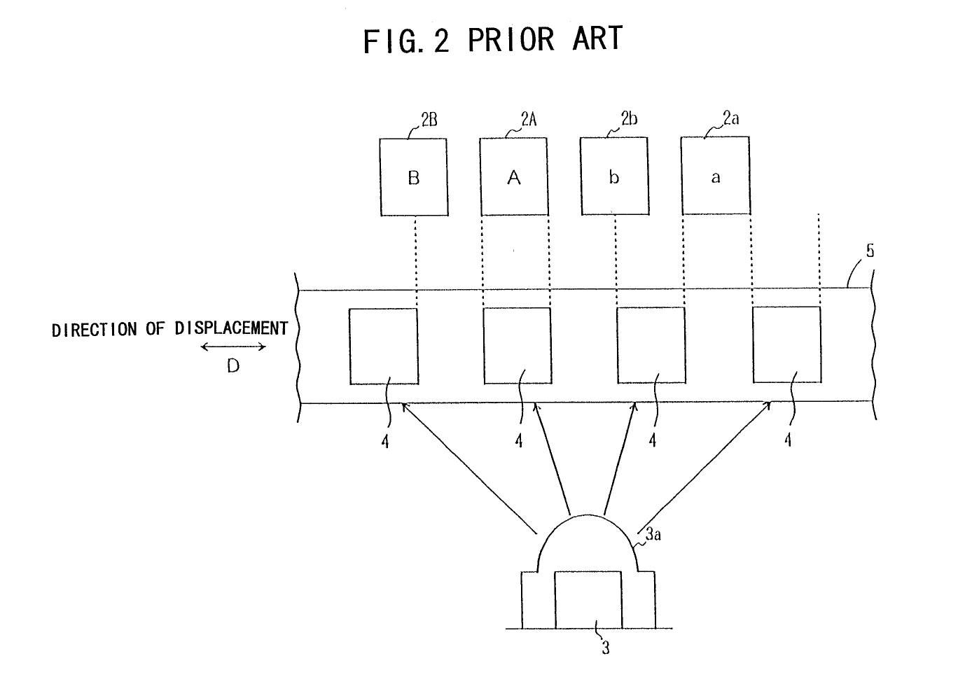

### DETAILED DESCRIPTION OF THE INVENTION

A detailed description will now be given of the encoder device according to the present invention, with reference to the accompanying drawings. It should be noted that identical or corresponding elements are given identical or corresponding reference numbers in all drawings, with detailed descriptions thereof given once and thereafter omitted.

A detailed description will now be given of an embodiment of an encoder device according to the present invention, with reference to the accompanying drawings.

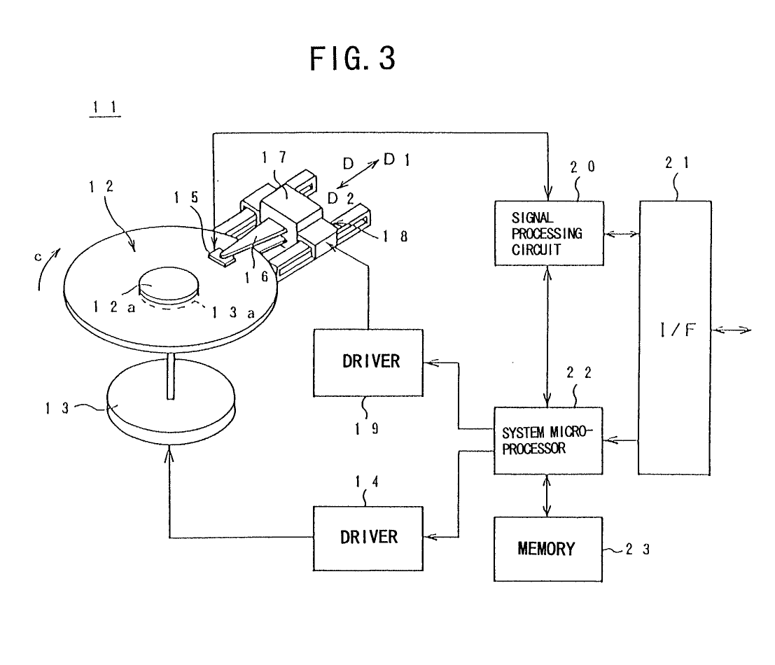

In order to facilitate an understanding of the invention, a description will first be given of a magnetic disk drive employing an embodiment of an encoder device according to the present invention, with reference to FIG. 3.

FIG. 3 is a structural diagram of a magnetic disk drive employing an embodiment of the encoder device according to the present invention.

As shown in FIG. 3, a magnetic disk 12 which is the recording medium is loaded into the magnetic disk drive 11. The magnetic disk 12 may for example be a high-density floppy disk. When loaded in the magnetic disk drive 11, a hub 12a of the magnetic disk 12 engages a chuck 13a provided on a rotor of a spindle motor 13.

The spindle motor 13 rotates in response to a rotational drive signal supplied from a driver 14. The rotation of the spindle motor 13 in a direction of arrow C shown in FIG. 3 rotates the magnetic disk 12 in the direction of arrow C.

Additionally, a magnetic head 15 is disposed opposite a recording surface of the magnetic disk 12. The magnetic head 15 is mounted at a tip of a suspension arm 16.

The other end of the suspension arm 16 is mounted on a head carriage 17. As the head carriage 17 moves in a direction of a radius of the magnetic disk 12 the magnetic head 15 mounted on the tip of the head carriage 17 is movably supported so as to move parallel to a surface of the magnetic disk 12.

The head carriage 17 engages an actuator 18. The actuator 18 moves in the direction of the radius of the magnetic disk 12, that is, in the direction of arrow D in FIG. 3, in response to a displacement control signal supplied from a driver 19, thereby moving the head carriage 17 in the direction of arrow D.

The magnetic head 5 is connected to a signal processing circuit 20. This signal processing circuit 20 supplies a recording signal to the magnetic head and also demodulates a reproduction signal reproduced at the magnetic head 15.

The signal processing circuit 20 is connected to an interface circuit 21 and to a system microprocessor 22. The interface circuit 21 is connected between the signal processing circuit 20 and a host computer not shown in the diagram, and acts as the interface between the signal processing circuit 20 and the host computer.

The system microprocessor 22 is connected to the signal processing circuit 20 and the interface circuit 21, as well as to a memory unit 23. The system microprocessor 22 accesses the memory unit 23 in response to present position information supplied from the signal processing circuit 20 and target position information supplied from the interface circuit 21, and controls the speed of displacement of the carriage head 17 according to a plurality of speed profiles stored in the memory unit 23. Additionally, the system microprocessor 22 repositions the head carriage 17 according to a tracking error signal supplied from the signal processing circuit 20.

It should be noted that a speed control operation mode for controlling speed of displacement as well as a position control mode for performing repositioning are provided in the system microprocessor 22. The speed control operation mode is selected when controlling the speed of displacement of the head carriage 17 and the position control mode is selected when repositioning the head carriage 17.

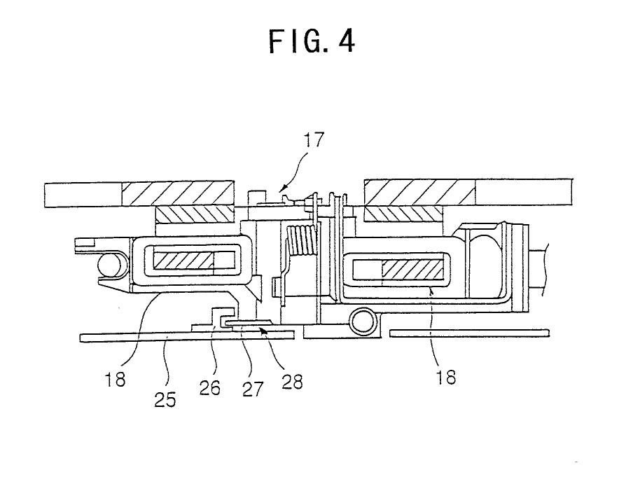

FIG. 4 is a front view of an installed state of an encoder device for detecting the position of the head carriage 17. As shown in the diagram, a photo-interruptor 26 is vertically mounted on a substrate 25 so as to oppose a bottom portion of the head carriage 17. A main scale 27 extending in a direction of displacement of the head carriage 17 is mounted on the bottom portion of the head carriage 17. As will be described later, the main scale 27 has openings spaced at regular intervals and is inserted within a slot of the photo-interruptor 26.

The above-described photo-interruptor 26 and the main scale 27 together form an encoder device 28. Accordingly, as the head carriage 17 moves in the direction of the radius of the magnetic disk 12, the main scale 27 moves within the slot of the photo-interruptor 26 and a signal is obtained from the photo-interruptor 26 corresponding to the displacement position of the head carriage 17.

A description will now be given of an embodiment of the encoder device 28 according to the present invention itself.

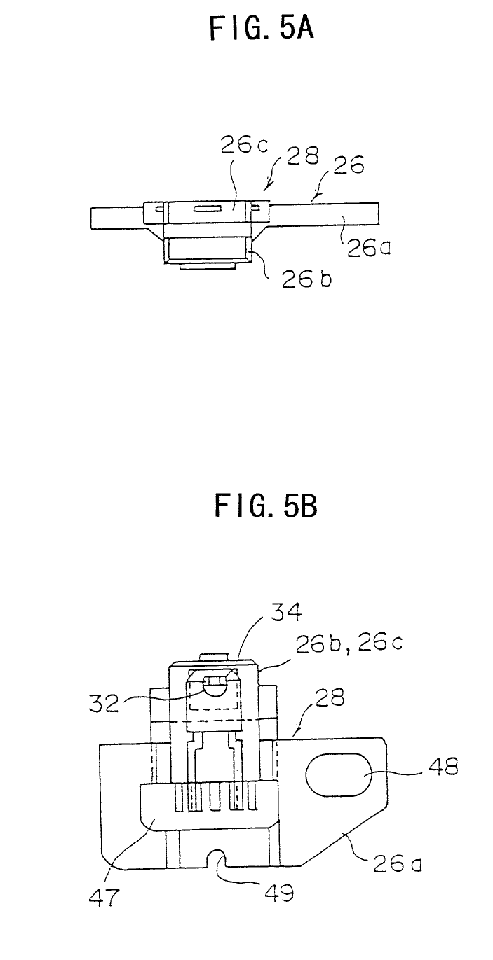

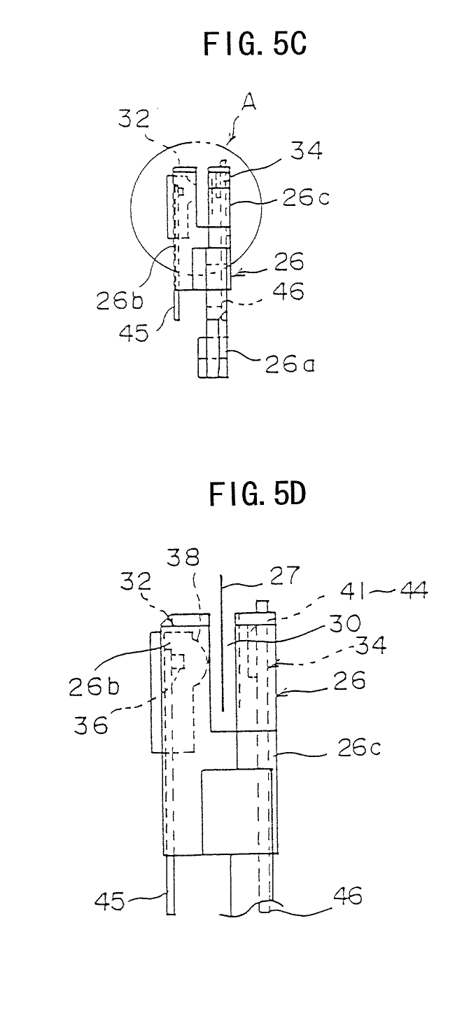

FIGS. 5A, 5B, 5C and 5D are front, plan, side and partial expanded views, respectively, of the encoder device 28 according to the present invention. As shown in the diagrams, the encoder device 28 comprises the photo-interruptor 26 and the main scale 27, and, as described above, the main scale 27 moves together with the head carriage 17 in the direction D of the radius of the magnetic disk 12. The photo-interruptor 26 is made from a single piece of plastic in such a way that a light source 32 and a light sensor portion 34 are disposed opposite each other across a slot 30 into which the main scale 27 is inserted. Further, the photo-interruptor 26 has a base 26a mounted on the substrate 25, a first holding portion 26b supported by the base 26a for supporting the light source 32 and a second holding portion 26c supported by the base 26a for supporting the light-receiving elements.

The light source 32 has a light-emitting element (light-emitting member) 36 consisting of a directional light-emitting photodiode and a convex lens 38 for aligning the beams of light emitted from the light-emitting element in parallel rays. Additionally, the light-receiving element 34 consists of four individual light-receiving elements, that is, light-receiving members, 41-44, for receiving light emitted via the lens 38 through the main scale 27. Two terminals 45 extending from the light-emitting element protrude from an edge portion of the first holding member 26b and five terminals extending from the first through fourth light-receiving elements protrude from an edge portion of the second holding portion 26c.

The base 26a has holes 47 through which each of the terminals of the four light-receiving elements 41-44 projects, an elongated hole 48 for mounting the base 26a on the substrate 25 and a convex portion 49 for positioning the base 26a on the substrate 25 when mounting the former on the latter.

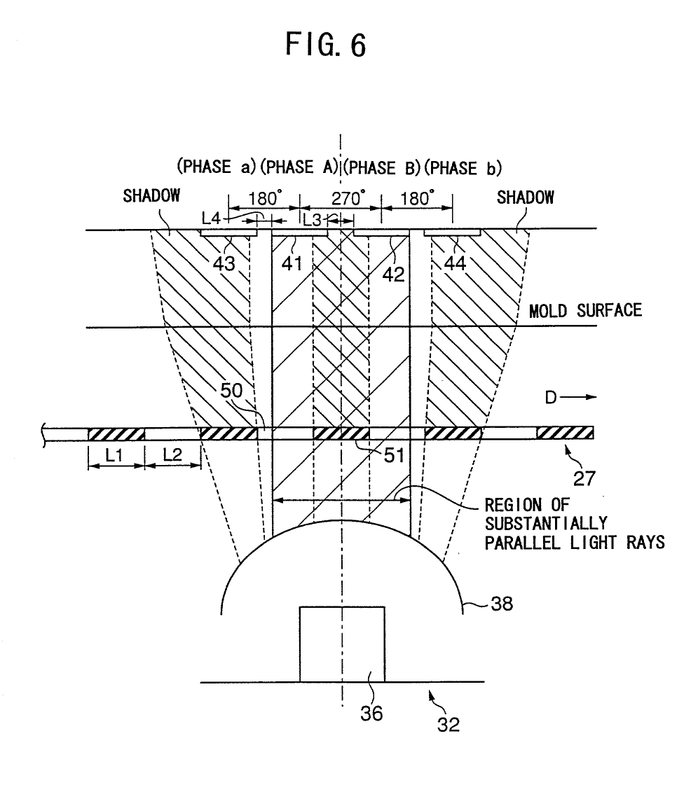

FIG. 6 is a plan view of the relative positions of the main scale 27, light source 32 and light-receiving elements. It should be noted that solid shield portions 51 of the main scale 27 which block the light emitted from the light source 32 are indicated in FIG. 6 by hatching, with the shadow formed by such shield portions 51 with respect to the light-receiving elements 41-44 also indicated by hatching.

As shown in FIG. 6, the main scale 27 is inserted between the lens 38 of the light source 32 and the four light-receiving elements 41-44. The main scale 27 is constructed so that, in a longer direction of the main scale 27, that is, in the direction of displacement of the main scale 27, openings 50 which admit the light emitted from the light source 32 alternate with the solid shield portions 51 which block the light emitted from the light source 32. It should be noted that the openings 50 have a width L1 in the longer direction, that is, the direction of displacement of the main scale 27, that is identical to the width L2 of the shield portions 51 in the longer direction, that is, the direction of displacement of the main scale 27.

Of the four light-receiving elements 41-44, the first and second light-receiving elements 41 and 42, which are positioned near a central axis of the lens 38 of the light source 32, receive the phase A and phase B light and are positioned so as to receive light at the same phase, and are separated from each other by a distance L3 smaller than L1 or L2. Therefore the first and second light-receiving elements are placed near the central axis so as to be able to receive the parallel rays of light emitted from the lens 38 of the light-emitting element 32.

Additionally, of the four light-receiving elements 41-44, the third and fourth light-receiving elements 43 and 44 receive the phase a and phase b light, that is, the inverted phase A and inverted phase B light, and are respectively positioned a slight distance L4 to the outside of the first and second light-receiving elements 41 and 42 that are positioned near the center of the lens 38 of the light source 32. In addition, the third and fourth light-receiving elements 43 and 44 are positioned so as to be located at the outer edges of the region of substantially parallel beams of light emitted from the light source 32 when the center of the region of substantially parallel rays of light is aligned with the center of the distance L3 separating the first and second light-receiving elements 41 and 42. As a result, it becomes possible to provide the light-receiving elements 41-44 at predetermined intervals and prevent the light-receiving elements 41-44 from contacting each other. The light-receiving elements 41-44 are thus positioned at reduced intervals and within a region bounded by and corresponding to the periphery of the lens 38, that is, positioned at intervals L3 and L4 along the main scale 27 so as to accommodate a reduction in size to a more compact lens 38. As a result, the encoder 28 is slimmer than the conventional art because the distance between the lens 38 and the light-receiving elements 41-44 is reduced.

Light emitted from the light-emitting element 36 is directed toward each of the light-receiving elements 41-44 by the lens 38 as beams of light, some portion of which passes through the openings in the main scale 27 and is received by the light-receiving elements 41-44. As a result, the light-receiving elements 41-44 output signals corresponding to changes in the amount of light passing through the openings 50 attendant upon the displacement of the main scale 27 as detected values.

It should be noted that the light-receiving elements 41-44 are made of clear molded plastic and that the main scale 27 is inserted between the light source 32 and the light sensor portion 34 so as to avoid contacting a surface of this mold.

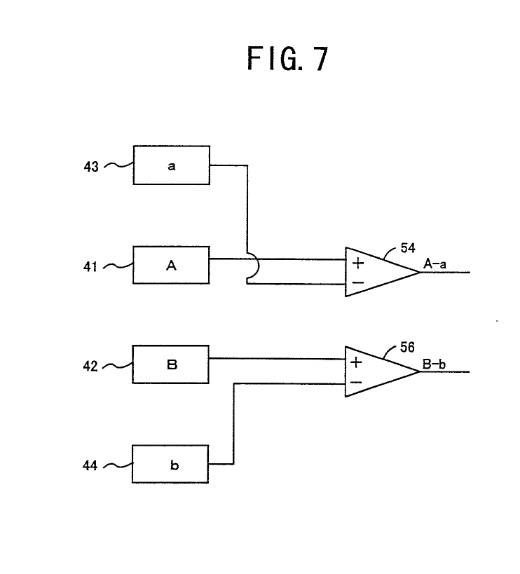

FIG. 7 is a block diagram showing a connection between each of the light-receiving elements 41-44 and a differential amplifier. As shown in the diagram, the first light-receiving element 41 is connected to the non-inverted input terminal (+) of the first differential amplifier 54 and the third light-receiving element 43 is connected to the inverted input terminal (−) of the first differential amplifier 54. As a result, the first differential amplifier 54 outputs a difference A−a between the output signal output from the phase A light-receiving element 41 and the output signal output from the phase a light-receiving element 43.

Additionally, the second light-receiving element 42 is connected to the non-inverted input terminal (+) of the second differential amplifier 56 and the fourth light-receiving element 44 is connected to the inverted input terminal (−) of the second differential amplifier 56. As a result, the second differential amplifier 56 outputs a difference B−b between the output signal output from the phase B light-receiving element 42 and the output signal output from the phase b light-receiving element 44.

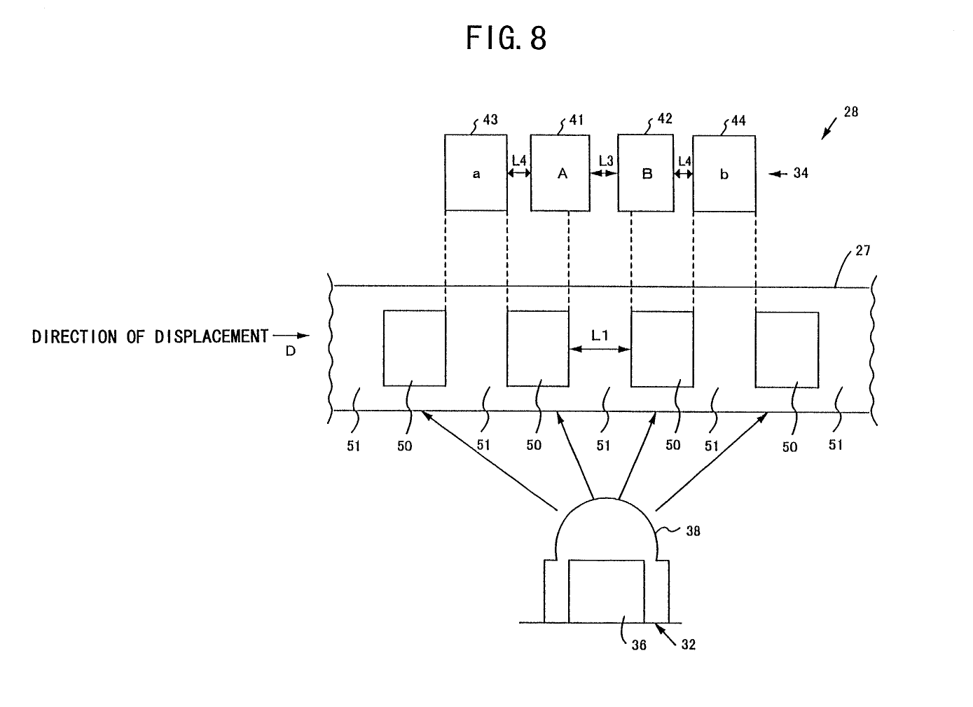

FIG. 8 is a schematized view of the relative positions of the light source 32, light-receiving elements 41-44 and openings 50 in the main scale 27. As shown in the diagram, the first light-receiving element 41 and the second light-receiving element 42 are disposed so as to be offset from the opening 50 by approximately a third, that is, overlapping a distance L1 between openings 50 by a third of such distance. The third and fourth light-receiving elements 43 and 44 are positioned so as to be squarely opposite the corresponding solid shield portions 51 of the main scale 27.

That is, the first light-receiving element 41 and the second light-receiving element 42 are positioned so as to be separated by a distance such that signals having a phase difference of approximately 270 degrees are obtained therefrom, and the first light-receiving element 41 and the third light-receiving element 43 are positioned so as to be separated by a distance such that signals having a phase difference of approximately 180 degrees are obtained therefrom.

Additionally, the second light-receiving element 42 and the fourth light-receiving element 44 are positioned so as to be separated by a distance such that signals having a phase difference of approximately 180 degrees are obtained therefrom.

In addition, the four light-receiving members are positioned so as to be in an order of the third light-receiving member 43, first light-receiving member 41, the second light-receiving member 42 and the fourth light-receiving member 44 in the direction D of displacement of the main scale 27, that is, from the left side of FIG. 8 to the right side of FIG. 8.

Accordingly, the light-receiving elements 41-44 are positioned more closely together than is conventionally the case, within a range opposite the lens 38, and are thus arranged in positions at which they are able to receive a full and sufficient number of the light rays emitted from the light source at greatest intensity. As a result, the distance between each of the light-receiving elements can be reduced while accurate, interference-free output signals can still be reliably obtained from each of the light-receiving elements.

In addition, by positioning the light-receiving elements 41-44 more closely together than is conventionally the case and within a range opposite the lens 38, the amount of light that each of the light-receiving elements 41-44 can receive is increased, the output from each of the light-receiving elements can be increased, and phase and amplitude fluctuations at the outer light-receiving elements 43 and 44 can be decreased. As a result, an appropriate level of light can be reliably secured for each of the light-receiving elements 41-44, such that the distance between the light source 32 and the light sensor portion 34 can be reduced while still maintaining an appropriate gap, thereby allowing the lens 38 and the encoder device 28 to be made slimmer and more compact.

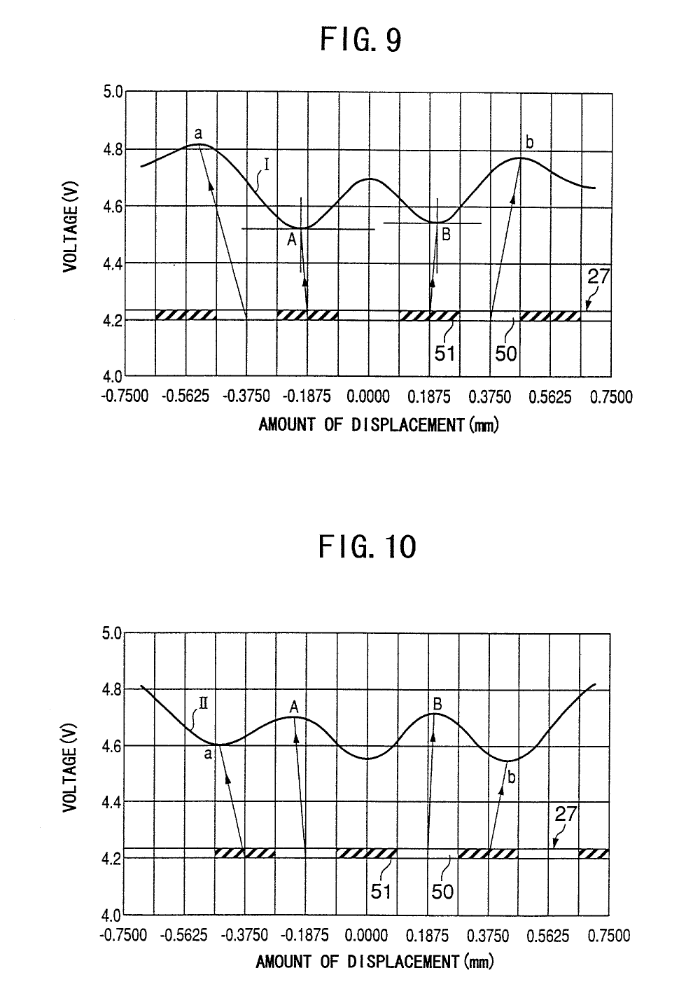

FIG. 9 is a graph (graph I) showing an output voltage waveform output from the light-receiving elements 41-44 in response to the position of the main scale 27. FIG. 10 is a graph (graph II) showing an output voltage waveform output from the light-receiving elements 41-44 when the main scale has been displaced in the direction of displacement from the position shown in FIG. 9 by an amount equal to the width L1 of one of the openings 50 in the main scale 27.

The positions of the light-receiving elements 41-44 described above are determined on the basis of the output voltage graphs I and II shown in FIGS. 9 and 10 as described above.

A description will now be given of detection operations of the encoder device 28.

In FIG. 8, the lens 38 of the light source 32 aligns the light emitted from the light-emitting element 36 in parallel beams and directs it toward the openings 50 in the main scale 27. Additionally, the central axis of the lens 38 is disposed so as to be positioned astride a line midway between the first light-receiving element 41 and the second light-receiving element 42. As a result, the first light-receiving element 41 and the second light-receiving element 42 are positioned with respect to the openings 50 in the main scale 27 so as to receive virtually identical amounts of light and output signals of virtually identical strength.

Additionally, although in FIG. 8 the third and fourth light-receiving elements 43 and 44 are disposed directly opposite solid shield portions 51 of the main scale 27, nevertheless these third and fourth light-receiving elements do receive a portion of the light dispersed from the openings 50 in the main scale 27. As a result, the third light-receiving element 43 is disposed at a position at which a signal having a phase difference of approximately 180 degrees with respect to the first light-receiving element 41 is obtained therefrom, and the fourth light-receiving element 44 is disposed at a position at which a signal having a phase difference of approximately 180 degrees with respect to the second light-receiving element 42 is obtained therefrom.

As the main scale 27 moves in the direction of displacement D, the surface area of the openings 50 in the main scale 27 opposite the first and fourth light-receiving elements 41 and 44 gradually increases and so, too, does the amount of light striking the first and fourth light-receiving elements 41 and 44. At the same time, the area of the openings 50 in the main scale 27 opposite the second and third light-receiving elements 42 and 43 gradually decreases, and so, too, does the amount of light striking the second and third light-receiving elements 42 and 43. As a result, the output of each of the light-receiving elements 41-44 is a signal that varies with the amount of light passing through the openings 50 in the main scale 27 and striking each of the light-receiving elements 41-44.

Thus, the output of the four light-receiving elements 41-44 varies according to the displacement position of the openings 50 in the main scale 27 as the main scale 27 moves in the direction of displacement D as shown in FIGS. 9 and 10. Displacement direction is detected from the phase differences between the output signals and the extent of the displacement can be calculated by counting the number of pulses.

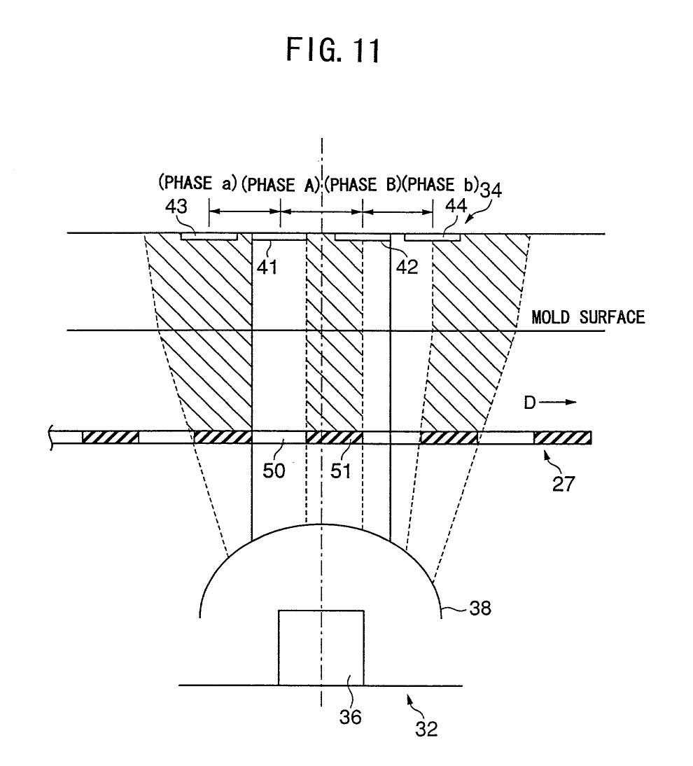

A description will now be given of first, second, third, fourth and fifth detection operation states performed by the light-receiving elements 41-44, with reference to FIG. 6 and FIGS. 11, 12, 13 and 14.

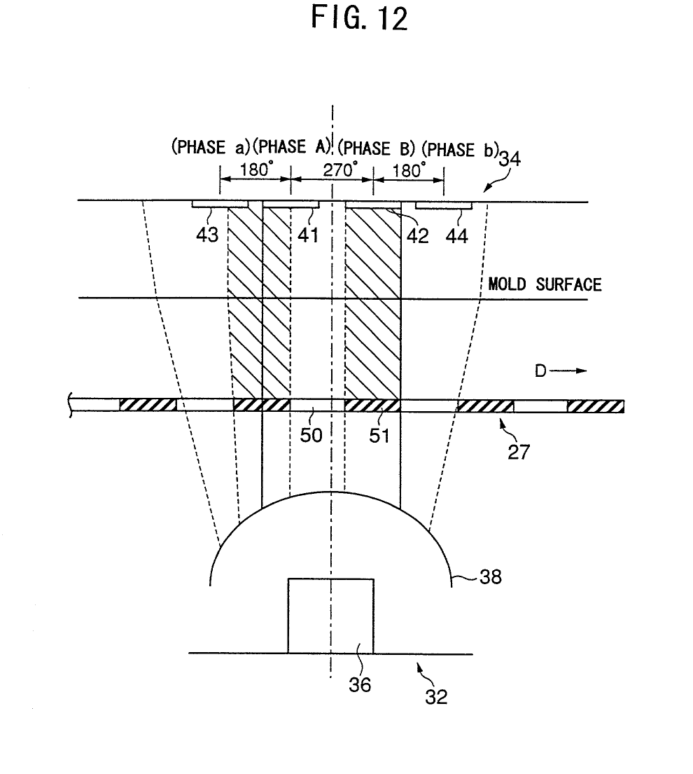

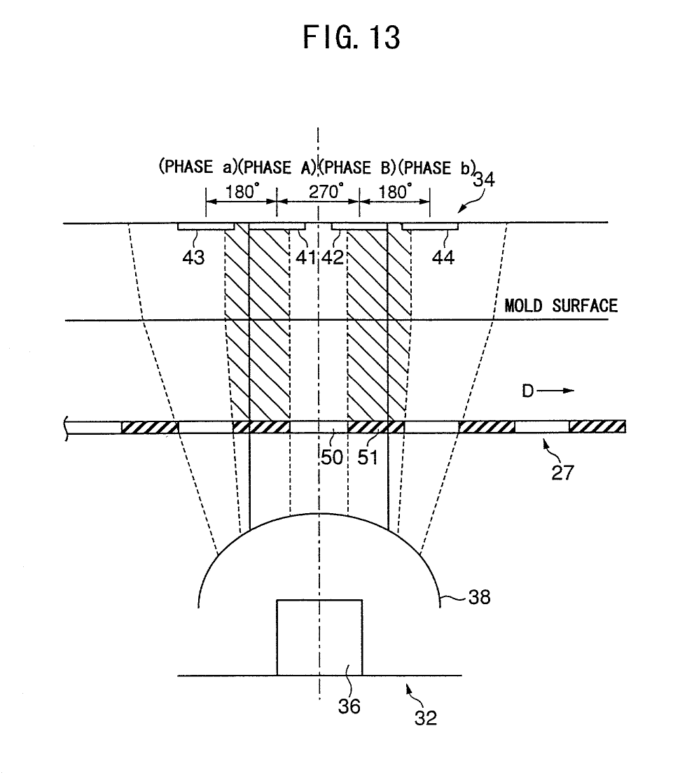

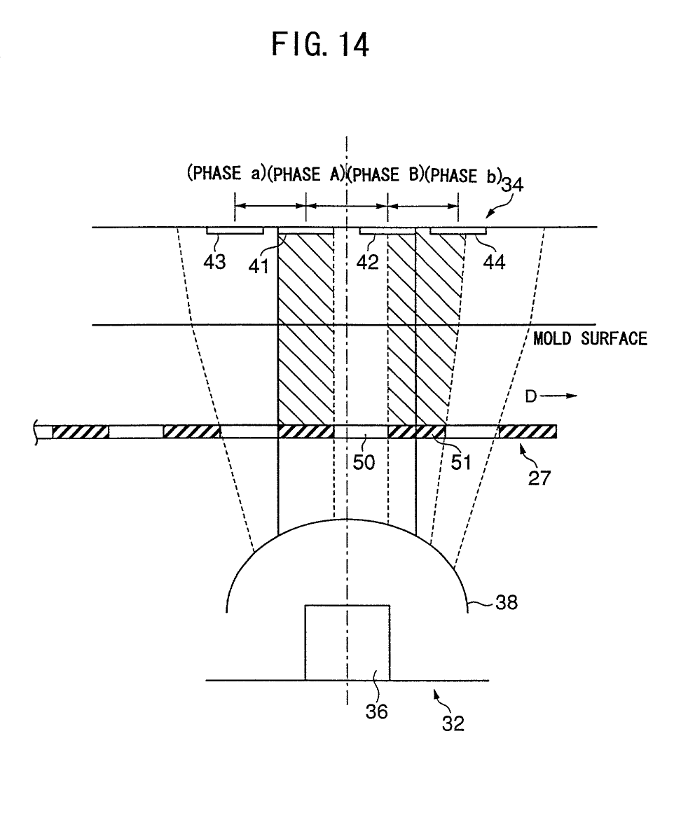

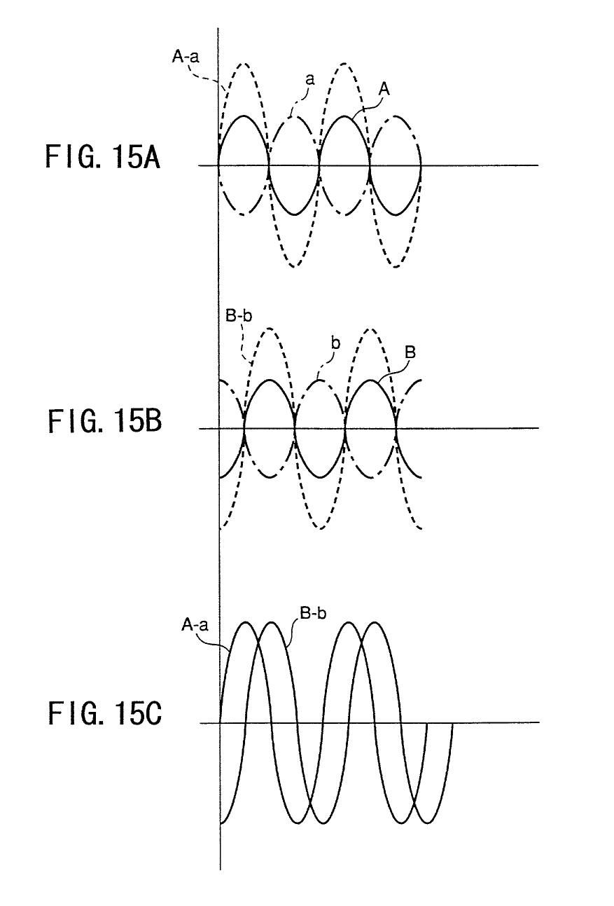

FIG. 6 is a plan view of the relative positions of the main scale, light source and light-receiving elements in a first detection operation state. FIG. 11 is a plan view of a second detection operation state in which the main scale 27 has moved in the direction of displacement D by an amount equivalent to ¼ L1 with respect to the state shown in FIG. 6. FIG. 12 is a plan view of a third detection operation state in which the main scale 27 has moved in the direction of displacement D by an amount equivalent to ½ L1 with respect to the state shown in FIG. 11. FIG. 13 is a plan view of a fourth detection operation state in which the main scale 27 has moved in the direction of displacement D by an amount equivalent to ¼ L1 with respect to the state shown in FIG. 12. FIG. 14 is a plan view of a fifth detection operation state in which the main scale 27 has moved in the direction of displacement D by an amount equivalent to ¼ L1 with respect to the state shown in FIG. 13.

A description will now be given of the first detection operation state, with reference to FIG. 6.

When the main scale 27 is at the position shown in the diagram, the third light-receiving element 43 is disposed opposite the solid shield portion 51 of the main scale 27. However, light that has passed through the opening 50 in the main scale 27 is dispersed outward thereby, with the result that the amount of light received is approximately 25 percent of maximum. At this time, the solid shield portion 51 in the main scale 27 is disposed opposite a point midway between the first and second light-receiving elements 41 and 42, such that approximately 75 percent of the surface area of each of the first light-receiving element 41 and the second light-receiving element 42 is disposed opposite the opening 50 in the main scale 27, with the result that the amount of light received is approximately 75 percent of maximum. Additionally, the fourth light-receiving element 44 is disposed opposite the solid shield portion 51 of the main scale 27. However, light that has passed through the opening 50 in the main scale 27 is dispersed outward thereby, with the result that the amount of light received is approximately 25 percent of maximum.

A description will now be given of the second detection operation state, with reference to FIG. 11.

When the main scale 27 has moved from the position shown in FIG. 6 in the direction of displacement D by an amount equivalent to ¼ of the length L1, the first light-receiving element 41 is disposed directly opposite the opening 50 in the main scale 27 and the amount of light received thereat increases to 100 percent of maximum. At this time, the second light-receiving element 42 is disposed so that approximately 50 percent of its surface area is opposite the solid shield portion 51 of the main scale, with the result that the amount of light received thereat decreases to 50 percent of maximum. The third light-receiving element 43 is disposed in such a way that the solid shield portion 51 of the main scale 27 is offset in the direction of displacement D from a position directly opposite the third light-receiving element 43, with the result that the amount of light received thereat decreases to virtually 0 percent of maximum. The fourth light-receiving element 44 is disposed so that approximately 50 percent of its surface area is opposite the opening 50 in the main scale 27, with the result that the amount of light received thereat increases to approximately 50 percent of maximum.

A description will now be given of the third detection operation state, with reference to FIG. 12.

When the main scale 27 has moved from the position shown in FIG. 11 by an amount equivalent to ½ of the length L1 in the direction of displacement D to the position shown in FIG. 12, the first light-receiving element 41 is disposed so that approximately 50 percent of its surface area is opposite the solid shield portion 51 in the main scale 27, with the result that the amount of light received thereat decreases to approximately 50 percent of maximum. At this time, the second light-receiving element 42 is disposed squarely opposite the solid shield portion 51 of the main scale 27, so the amount of light received thereat decreases to virtually 0 percent of maximum. The third light-receiving element 43 is disposed so that approximately 50 percent of its surface area is opposite the opening 50 in the main scale 27, with the result that the amount of light received thereat increases to approximately 50 percent of maximum. The fourth light-receiving element 44 is disposed directly opposite the opening 50 in the main scale 27 and the amount of light received thereat increases to 100 percent of maximum.

A description will now be given of the fourth detection operation state, with reference to FIG. 13.

When the main scale 27 has moved from the position shown in FIG. 12 by an amount equivalent to ¼ of the length L1 in the direction of displacement D to the position shown in FIG. 13, the first light-receiving element 41 is disposed so that approximately 75 percent of its surface area is opposite the solid shield portion 51 in the main scale 27, with the result that the amount of light received thereat decreases to approximately 25 percent of maximum. At this time, the second light-receiving element 42 is disposed so that approximately 25 percent of its surface area is opposite the opening 50 in the main scale 27, so the amount of light received thereat increases to approximately 25 percent of maximum. The third light-receiving element 43 is disposed so that approximately 75 percent of its surface area is opposite the opening 50 in the main scale 27, with the result that the amount of light received thereat increases to approximately 75 percent of maximum. The fourth light-receiving element 44 is disposed so that approximately 25 percent of its surface area is opposite the solid shield portion 51 in the main scale 27, so the amount of light received thereat decreases to 75 percent of maximum.

A description will now be given of the fifth detection operation state, with reference to FIG. 14.

When the main scale 27 has moved from the position shown in FIG. 13 by an amount equivalent to ¼ of the length L1 in the direction of displacement D to the position shown in FIG. 14, the first light-receiving element 41 is disposed directly opposite the solid shield portion 51 in the main scale 27, with the result that the amount of light received thereat decreases to approximately 0 percent of maximum. At this time, the second light-receiving element 42 is disposed so that approximately 50 percent of its surface area is opposite the opening 50 in the main scale 27, so the amount of light received thereat increases to approximately 50 percent of maximum. The third light-receiving element 43 is disposed directly opposite the opening 50 in the main scale 27, with the result that the amount of light received thereat increases to approximately 100 percent of maximum. The fourth light-receiving element 44 is disposed so that approximately 50 percent of its surface area is opposite the solid shield portion 51 in the main scale 27, so the amount of light received thereat decreases to 50 percent of maximum.

Further, when the main scale 27 moves a predetermined distance equivalent to ¼ of L1 in the direction of displacement D to the position shown in FIG. 14, the unit returns to the first detection state shown and described with respect to FIG. 6. Repetition of the above-described detection states results in the generation of output signals corresponding to the amount of displacement of the main scale 27.

FIGS. 15A, 15B and 15C are diagrams showing waveforms of differential signals obtained from the encoder device according to the above-described embodiments of the present invention. FIG. 15A is a diagram of a waveform of a first differential output signal obtained from the difference between phase A and phase a. FIG. 15B is a diagram of a waveform of a second differential output signal obtained from the difference between phase B and phase b. FIG. 15C is a diagram showing a waveform indicating a phase difference between the above-described first differential output signal and the above-described second differential output signal.

As shown in FIG. 15A, in the present embodiment, the phase A and the inverted phase A (=a) have a phase difference of approximately 180 degrees, with the result that the first differential output signal A−a output from the first differential amplifier 54 (see FIG. 7) is a sine curve amplified as shown by the dotted line in FIG. 15A.

As shown in FIG. 15B, in the present embodiment, the phase B and the inverted phase B (=b) have a phase difference of approximately 180 degrees, with the result that the second differential output signal B−b output from the second differential amplifier 54 (see FIG. 7) is a sine curve amplified as shown by the dotted line in FIG. 15B.

Accordingly, the first light-receiving elements 41-44 are disposed so that the first differential output signal A−a obtained by differentially amplifying the output signal from the first light-receiving element 41 and the output signal from the third light-receiving element 43, and the second differential output signal B−b obtained by differentially amplifying the output signal from the second light-receiving element 42 and the output signal from the fourth light-receiving element 44, have the same period and first differential output signal a and second differential output signal b have a phase difference of 90 degrees.

As a result, it is possible to determine the direction of displacement of the head carriage 17 provided on the main scale 27 from the difference in phase between the above-described first differential output signal A−a and the above-described second differential output signal B−b. Moreover, it is possible to determine the speed of displacement from the period of each signal and at the same time it is possible to determine the displacement position from the number of pulses of each signal.

It will be appreciated by those of skill in the art that the encoder device according to the present invention, though described with reference to application in a magnetic disk drive 11, the present invention is nevertheless clearly able to be used to detect displacement of a moving body in other devices as well.

The above description is provided in order to enable any person skilled in the art to make and use the invention and sets forth the best mode contemplated by the inventor of carrying out the invention.

The present invention is not limited to the specifically disclosed embodiments, and variations and modifications may be made without departing from the scope and spirit of the present invention.

The present application is based on Japanese Priority Application No. 2000, 128050, filed on Apr. 27, 2000, the entire contents of which are hereby incorporated by reference.

What is claimed is:

1. An encoder device comprising:
a main scale with a plurality of slit-like openings at regular intervals;
a light-emitting element for emitting and directing substantially parallel rays of light toward the main scale;
a light-receiving element including four light-receiving members for receiving light emitted from the light-emitting means via the slit-like openings in the main scale; and
a detection unit for detecting a displacement of the main scale by using output signals output from the light-receiving element,
the first light-receiving member and the second light-receiving member positioned a distance apart such that a signal having a phase difference of approximately 270 degrees is obtained therefrom,
the first light-receiving member and the third light-receiving member positioned a distance apart such that a signal having a phase difference of approximately 180 degrees is obtained therefrom,
the second light-receiving member and the fourth light-receiving member positioned a distance apart such that a signal having a phase difference of approximately 180 degrees is obtained therefrom,
the four light-receiving members being positioned so as to be in an order of the third light-receiving member, first light-receiving member, the second light-receiving member and the fourth light-receiving member in the direction of displacement of the main scale.

2. The encoder device as claimed in claim 1, wherein the detection unit comprises:
a first differential amplifier for generating a first differential output signal by differentially amplifying an output signal from the first light-receiving member and an output signal from the third light-receiving member; and
a second differential amplifier for generating a second differential output signal by differentially amplifying an output signal from the second light-receiving member and an output signal from the fourth light-receiving member,
the first differential output signal and the second differential out put signal having an identical period and a predetermined phase difference.

3. The encoder device as claimed in claim 1, wherein the third light-receiving member and the fourth light-receiving member are positioned so as to be disposed at outer sides of a region of substantially parallel rays of light generated from the light-emitting element when a center of the region of substantially parallel rays of light is aligned with a center position between the first light-receiving member and the second light-receiving member.
